(19) United States
(12) Patent Application Publication
(10) Pub. No.: US 2009/0095617 A1
(43) Pub. Date: Apr. 16, 2009

(54) BIAS SPUTTERING FILM FORMING PROCESS AND BIAS SPUTTERING FILM FORMING APPARATUS

(75) Inventors: Myounggoo LEE, Shizuoka (JP); Yoshihiro OKAMURA, Shizuoka (JP); Kazuyuki TOMIZAWA, Shizuoka (JP); Satoru TOYODA, Shizuoka (JP); Narishi GONOHE, Shizuoka (JP)

Correspondence Address: ARENT FOX LLP, 1050 CONNECTICUT AVENUE, N.W., SUITE 400, WASHINGTON, DC, 20036, US

(73) Assignee: ULVAC, Inc., Kanagawa (JP)

(21) Appl. No.: 12/333,955

(22) Filed: Dec. 12, 2008

Related U.S. Application Data
(63) Continuation of application No. 10/658,460, filed on Sep. 10, 2003, now abandoned.

(30) Foreign Application Priority Data
Sep. 13, 2002 (JP) 2002/268019

(51) Int. Cl. C23C 14/34

(52) U.S. Cl. 204/192.15; 204/192.12; 204/298.06

(57) ABSTRACT

The present invention provides a bias sputtering film forming process and film forming apparatus that can form a coating film having a good film thickness distribution in a minute coated surface of a complicated shape, such as contact holes, through-holes and wiring grooves, especially for the sidewall portions thereof.

To a bias sputtering film forming apparatus provided with a sputtering cathode 4 and a substrate stage 5 holding a target 6 and a substrate 7 facing to each other, respectively, in a vacuum chamber 1 having a sputtering gas inlet 3 and a vacuum exhaust port 2, a power source 9 of a variable output for the substrate stage 5 and a control system 10 are connected. The substrate bias voltage value when the cathode voltage is made set to a predetermined voltage previously, and the target is parted from the substrate by a predetermined distance; and the thickness distribution of the thin film on each surface corresponding to this substrate bias voltage value are stored in the control system 10 as reference data. The substrate bias voltage value to make the film thickness substantially uniform in the film forming of each surface is selected from the reference data to be a bias voltage function that makes this a variable, and the output of the power source is controlled by this function.

### BACKGROUND OF THE INVENTION

1. Field of the Invention

The present invention relates to a film forming process and a film forming apparatus using a bias sputtering method, and more specifically to a thin film forming process for forming a barrier layer, or a seed layer used in film forming by electrolytic plating having a substantially uniform thickness on the sidewalls and bottoms of contact holes, through-holes and wiring grooves formed on the surface of a semiconductor substrate.

2. Description of the Related Art

In the semiconductor industry, the scale down is advancing, and the aspect ratio (depth/hole diameter or groove width) of holes or wiring grooves formed on a substrate tends to be bigger and bigger. Generally, in semiconductor wirings using copper, the formation of a barrier layer, or a seed layer for electrolytic plating having a thickness of several tens to several hundreds angstroms on the internal surfaces (sidewalls and bottoms) of such holes and grooves is required. Particularly for the barrier layer, since a conductive material having a large resistance is used, it is ideal that the barrier layer of a minimum thickness that can maintain the diffusion preventing effect is formed on the entire surfaces of the internal walls of holes and grooves. Furthermore, in view of expenses and process stability, such a requirement is particularly strong for the sputtering film forming process.

Heretofore, in sputtering film forming processes, the bias sputtering process has been known as means to improve coverage for the irregularity of substrate surfaces. This is a process wherein a DC power or a RF power is supplied to both the target and the substrate electrode, and a bias voltage is applied to the surface of a substrate placed on the substrate electrode to form a thin film.

As this type of bias sputtering processes, for example, processes disclosed in Patent Reference 1 and Patent Reference 2 have been known. These are constituted to generate a bias voltage at the substrate, and form a film of a uniform thickness on the internal wall portions of the holes by preventing the formation and growth of overhangs at the hole openings by the inverse sputtering effect, and re-sputtering the film forming material deposited on the bottom portions of the holes to make the material sticking on the sidewall portions.

The above-described holes and wiring grooves have a high aspect ratio and a minute and complicated shape, and when a barrier film is formed on them, it is required to form an extremely thin coating film having a uniform thickness on the entire surface of the substrate including the internal walls and bottom portions of the holes and wiring grooves for obtaining a reliable diffusion preventing effect.

According to the studies by the present inventors, although film forming using only a constant substrate bias voltage as in the above-described prior art is effective for substrates having holes and wiring grooves of an aspect ratio of about 5 or less, if the aspect ratio is larger, the locations where re-sputtered particles deposit are concentrated to a certain limited location on the sidewall portions in the holes and grooves. In other words, it was found difficult to make the film thickness uniform throughout the entire internal wall surfaces of the holes and grooves because the coating film formed on the sidewall portions by re-sputtered particles have a certain film thickness distribution. Specifically, it was found that films are formed having different film thickness distribution subject to the magnitude of substrate bias voltages, the quantities of vertical components of sputtered particles coming from a target, the size of formed overhangs, and the like.

Furthermore, as the measure to improve coating properties, there has been known a bias controlling method by increasing the bias intensity in the initial period of film forming, and decreasing the bias intensity in the final period of film forming, as described in Patent Reference 3. Therefore, this method attempted to improve the coating properties of the sidewall portions of the above-described contact holes and wiring grooves. In this case, however, it was found that this method cannot be applied to semiconductor processes since the bias intensity is increased in the initial period of film forming, the underlying layers are beaten with strong energy of the generated ions resulting in a large damage.

### Patent Reference 1

Japanese Patent Application Laid-Open No. 8-264487/1996 (pp. 5-10, FIGS. 2 and 3)

### Patent Reference 2

Japanese Patent No. 2602276 (pp. 4-6, FIGS. 1 and 13)

### Patent Reference 3

Japanese Patent No. 2711503 (pp. 2-3, FIG. 1)

In consideration of the above-described problems, the object of the present invention is to provide a process and an apparatus for forming a thin film having good coating properties for the internal wall surfaces of contact holes, through-holes, wiring grooves and the like of a high aspect ratio.

### SUMMARY OF THE INVENTION

In order to solve the above-described problems, the present invention provides a bias sputtering film forming process for forming a thin film by applying both voltages of a cathode voltage and a substrate bias voltage, wherein a thin film is formed on a substrate whereon an irregularity is formed in the state wherein only the cathode voltage out of the both voltages is applied, and sputtering film forming is performed while varying the substrate bias voltage so that the thickness of the thin film formed on the surfaces on the sidewalls and on the bottoms of the irregularity is substantially uniform.

Here, the reason why only a cathode voltage is applied for initial film forming is to prevent the damage or deterioration of underlying layers when a substrate bias voltage is applied from the initial stage.

Therefore, it is preferred that the applied substrate voltage is low in the initial stage of bias sputtering. However, if the film is formed under conditions to obtain a sufficient film thickness in the initial stage of film forming, it is not necessary to start with a low substrate bias voltage.

When a film is formed on the surface of a substrate having irregularities such as contact holes using a bias sputtering film forming process, the film thickness distribution on the surfaces of sidewalls and of hole bottoms tends to correlate with the intensity of the applied substrate bias voltage. This correlation is marked in the height direction of the sidewall surfaces, and marked on the bottom surfaces of the holes. Therefore, there must be the bias voltage functions (substrate bias voltages, applying time and the like are variables) that can eliminate difference in the thickness of the coating films in the height direction of the surfaces of sidewalls, and by controlling the increase and decrease of substrate bias voltages with such a function, difference in the thickness of the coating films in the height direction of the surfaces of sidewalls of the irregular portion can be eliminated, and the film can be uniform.

Similarly, there must be the bias voltage functions that can eliminate difference in the thickness of the coating films between in the center side and in the edge side of the substrate on the bottom surface of the holes, and by controlling the increase and decrease of substrate bias voltages, difference in the thickness of the coating film formed on the surface of the bottoms of the irregular portion can be eliminated.

Furthermore, not only by individually eliminating the non-uniformity of the film thickness in the height direction of the sidewall portion and on the bottom surfaces, but also by suitably selecting each of the above-described bias voltage functions, difference in the film thickness of both the sidewall surfaces and bottom surfaces can be eliminated simultaneously.

Thereby, even if the coating surface has minute and complicated irregularity, the coating film of a uniform thickness can be formed on the entire surface of the substrate.

When the bias sputtering film forming is thus performed while varying the substrate bias voltage, the amount of sputtered particles entering the substrate can be controlled by also varying the cathode voltage. And, by selecting the optimum combination of the conditions, a thin film having excellent coating properties can be obtained in which the uniformity thereof is further improved.

In this case, by making sputtered particles coming from the target enter substantially vertically, the formation of overhangs produced at the openings such as holes can be prevented, and a considerable quantity of deposited films can be secured on the bottoms of the irregularity. Therefore, if bias sputtering film forming is performed using the deposited films on the bottoms as the film forming source, film forming on the sidewalls can be assured without damaging underlying layers, and the selection range of the bias voltage function that enables the above-described uniform film formation will be widened.

The above-described substantially vertical entrance of sputtered particles can be realized, for example, by setting the distance between the target and the substrate to a distance larger than the diameter of the wafer to be used, and performing sputtering film forming using a degree of vacuum wherein the mean free path of the sputtered particles is longer than the distance. Although there is a case where a collimator is inserted between the substrate and the target, this method must be used carefully because the collimator itself may be sputtered or may become the source of dust.

Since the formed coating film has good coating properties, especially a substantially uniform film thickness distribution on the internal surfaces of irregularity (sidewall surfaces and bottom surfaces), it is effective as a barrier layer for copper wiring or a seed layer for electrolytic plating film forming.

Thereby, when the film is used as a barrier layer of a minimum thickness keeping diffusion preventing functions is formed, the advantage of using copper wiring having a lower electric resistance than aluminum can be utilized efficiently. When the film is used as a seed layer for electrolytic plating, a uniform plating film can be formed, and the occurrence of voids in the wiring can be inhibited.

In order to perform the above-described bias sputtering film forming, a bias sputtering film forming apparatus equipped with an AC or DC power source of variable outputs to the substrate electrode, and with a control system was constituted; in the control system, the cathode voltage was previously set to a predetermined voltage, the substrate bias voltage value when the substrate and the target was parted by a predetermined distance and the thickness distribution of thin films on each surface corresponding to this substrate bias voltage value were stored as reference data; the substrate bias voltage value that makes the film thickness substantially uniform when film forming were performed on each surface was selected from the reference data to make the bias voltage function using it as the variable; and the output of the power source was controlled by this function.

The term “bias voltage function” used herein does not mean just a mathematical function, but also means that substrate bias voltage values and the thickness distribution of thin films on each surface corresponding to the substrate bias voltage values are stored as reference data to produce a data base, and the substrate bias voltage is suitably varied so as to correct the film thickness accordingly. The bias voltage function also include that the substrate bias voltage is made “zero” in an adequate time period during bias sputtering film forming.

Furthermore, it is needless to mention that better coating properties can be obtained by adequately varying cathode voltages and controlling the quantity of incoming sputtered particles during such bias sputter film forming. In other words, the bias sputtering film forming apparatus is further provided with a power source of variable output against the cathode, and in the bias sputtering film forming performed by controlling the output of the substrate power source based on the bias voltage functions mentioned above, the control system also controls the output of the cathode power source. Due to the variation of the cathode voltage, a thin film having excellent coating properties can be obtained in which the uniformity thereof is further improved.

### BRIEF DESCRIPTION OF THE DRAWINGS

FIG. 1 is a schematic sectional view showing a sputtering film forming apparatus of the present invention;

FIGS. 2 (a) to (c) are diagrams showing various shapes of contact holes covered with barrier metals;

FIG. 3 is a graph showing the correlation between overhang, step coverage, and substrate bias supplying electric power;

FIG. 4 (a) is a top view showing the location of the contact hole on the substrate, FIG. 4 (b) is a schematic sectional view showing the contact hole on the substrate, and FIG. 4 (c) is a graph showing the correlation between the minimum side coverage height and substrate bias supplying electric power;

FIG. 5 (a) is a schematic sectional view showing the contact hole located in the edge portion of the substrate, and FIG. 5 (b) is a graph showing the correlation between the side coverage at each location on the sidewalls and substrate bias supplying electric power;

FIG. 6 (a) is a top view showing the locations of two contact holes on the substrate, and FIG. 6 (b) is a graph showing the coverage distribution ranges in Embodiment 1 and Comparative Embodiment 1; and

FIG. 7 is graph showing the thickness distribution of Ta film in the height direction on the sidewall portions of the hole in Embodiment 2 and Comparative Embodiment 2.

### DESCRIPTION OF REFERENCE NUMERALS

1 Film forming chamber
2 Exhaust port
3 Sputtering gas inlet
6 Target
7 Substrate
8 Cathode power source
9 Substrate bias power source
10 Control system
20 Contact hole
21 Sidewall portion
22 Opening portion
23 Bottom portion

### DETAILED DESCRIPTION OF THE PREFERRED EMBODIMENTS

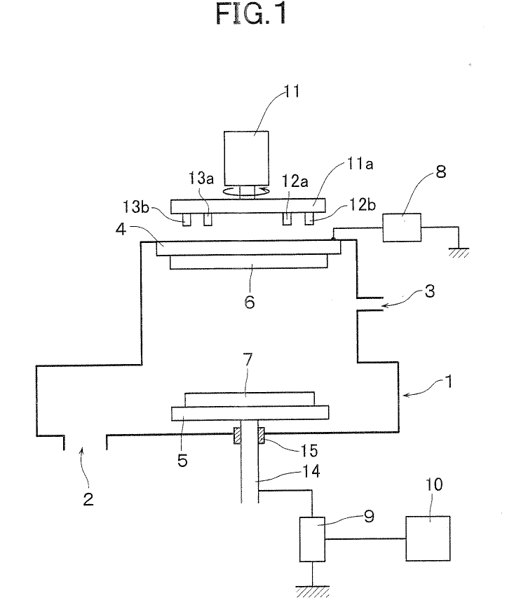

FIG. 1 is a schematic sectional view showing a sputtering film forming apparatus for implementing the bias sputtering film forming process of the present invention. A film forming chamber 1 is so constituted as to be provided with an exhaust port 2 connected to a vacuum exhaust system (not shown) and a sputtering gas inlet 3 on the sidewall thereof, a sputtering cathode 4 and a substrate stage 5 are disposed therein, and a Ta target 6 placed on the sputtering cathode 4 and a silicon substrate 7 placed on the substrate stage 5 face to each other. The distance between the target 6 and the substrate 7 is equal to or larger than the diameter of the substrate 7 (200 mm).

Furthermore, the sputtering cathode 4 is connected to a cathode power source 8 outside the apparatus, the substrate stage 5 is connected to an AC or DC power source 9 outside the apparatus, and the power source 9 is connected to a control system 10 for controlling the substrate bias voltage. On the location out of the apparatus immediately above the cathode 4 is disposed a holder 11a rotatably driven by a motor 11, and magnets 12a and 13a (of N pole or S pole), and 12b and 13b (of S pole or N pole) mounted on the holder 11a rotate during sputtering film forming to perform magnetron sputtering film forming. The connecting portion 14 connecting the substrate stage 5 and the power source 9 has a structure to intrude into the film forming chamber 1 through an insulator 15.

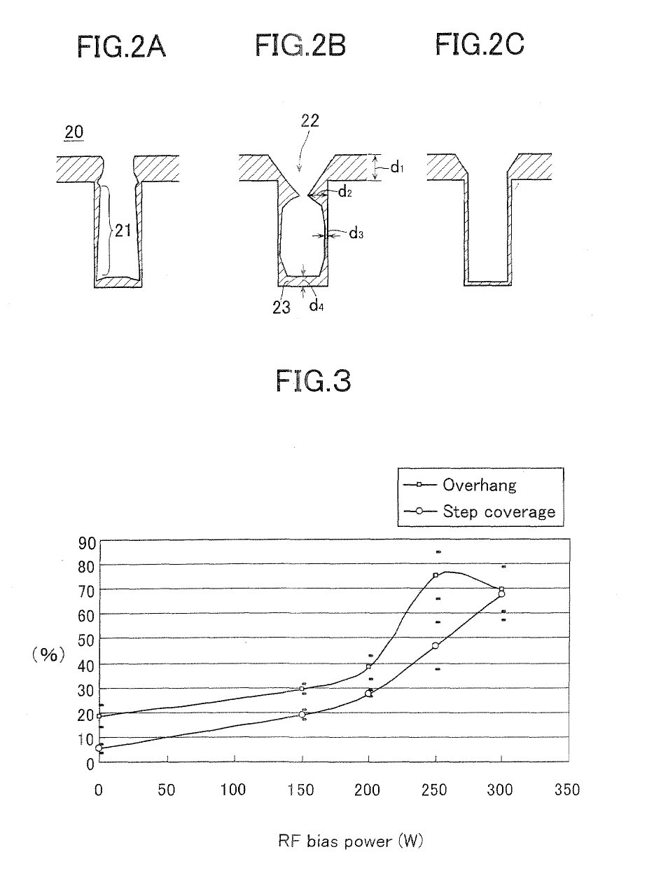

The semiconductor substrate 7 is provided with a contact hole 20 of a minute concave shape as shown in FIG. 2 in an insulating film formed on the substrate surface for wiring with conductive material. In order to prevent the diffusion of the wiring material such as copper into the SiO₂ insulating film, a conductive material having a relatively high electric resistance such as Ta, TaN, TiN and WN (barrier metal or diffusion-preventing film) is used for coating to prevent the deterioration of the performance of the semiconductor.

It is required that such a barrier metal film maintains a good coating accuracy, that is a thin and uniform film thickness, and the entire internal surfaces of the hole is coated. The film forming apparatus shown in FIG. 1 can be used for forming a barrier metal film consisting of Ta on the internal wall portion of the contact holes using the bias sputtering process.

In using the bias sputtering process, the substrate bias voltage, that is the electric power applied to the substrate stage 5 from the power source 9 through the connecting portion 14 in FIG. 1 significantly affects the formation of the above-described coating film. For example, when the substrate bias voltage is in short, the coating film formed on the sidewall portion 21 of the hole 20 tends to have a thickness smaller than desired as shown in FIG. 2 (a); and when the substrate bias voltage is in excess, a protrusion called overhang is often formed at the opening portion 22 of the hole 20 as shown in FIG. 2 (b). Although the formation of this overhang is prevented to some extent by increasing the distance between the target 6 and the substrate 7 as in the apparatus of FIG. 1 so as to increase the vertical component of sputtered particles impinging to the substrate surface, since the substrate bias voltage factor also contributes, in order to obtain an ideal barrier metal shape as shown in FIG. 2 (c), it is important to adjust the substrate bias voltage carefully.

Now, if the ratio of the thickness d₃ of the coating film formed on the sidewall portion 21 in FIG. 2 to the thickness d₁ of the coating film formed on the surface of the substrate is defined as side coverage; the ratio of the thickness d₄ of the coating film formed on the bottom portion 23 to the film thickness d₁ is defined as step coverage; and the ratio of the characteristic film thickness d₂ of the opening portion 22 to the film thickness d₁ is defined as overhang; the characteristic values of the coating film represented by these ratios tend to significantly correlated to the intensity of the substrate bias voltage.

An example thereof is shown in the graph of FIG. 3. Here, an RF power source is used as a power source for generating bias, and the ordinate in the graph Indicates the values of overhang and step coverage. When the substrate bias supply power is 0 W, that is, in ordinary sputtering film forming, the values of overhang and step coverage are very small, and thus the covering performances are unreliable. When the substrate bias supply power is increased, step coverage is increased and thus the covering performances are improved; however, since overhang is also increased, simple increase in the substrate bias supply power alone cannot achieve the ideal shape shown in FIG. 2 (c).

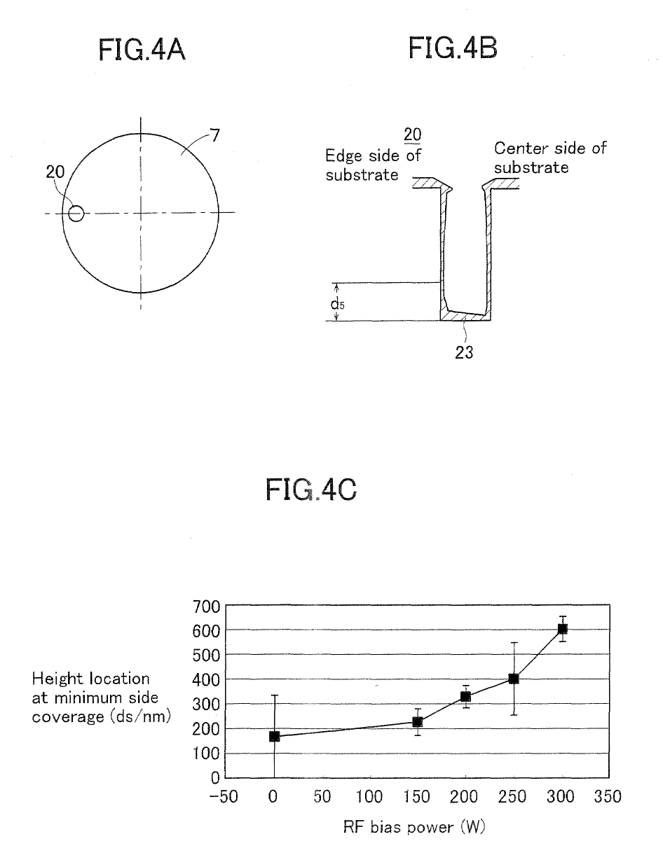

The above-described correlation between the bias voltage and the thickness of the coating film examined in further detail is shown in FIG. 4. FIGS. 4 (a) and (b) are a top view and a sectional view of a hole 20 located on the edge side of a substrate 7, respectively. The correlation is observed between the height d₅ of the minimum side coverage portion, that is, the location of the minimum film thickness in the film thickness distribution of the sidewall portion, from the bottom portion 23, and the substrate bias supply power, as shown in FIG. 4 (c). It is known from FIG. 4 (c) that the height d₅ of the minimum side coverage shifts toward the opening portion 22 accompanied with the increase in the substrate bias supply power.

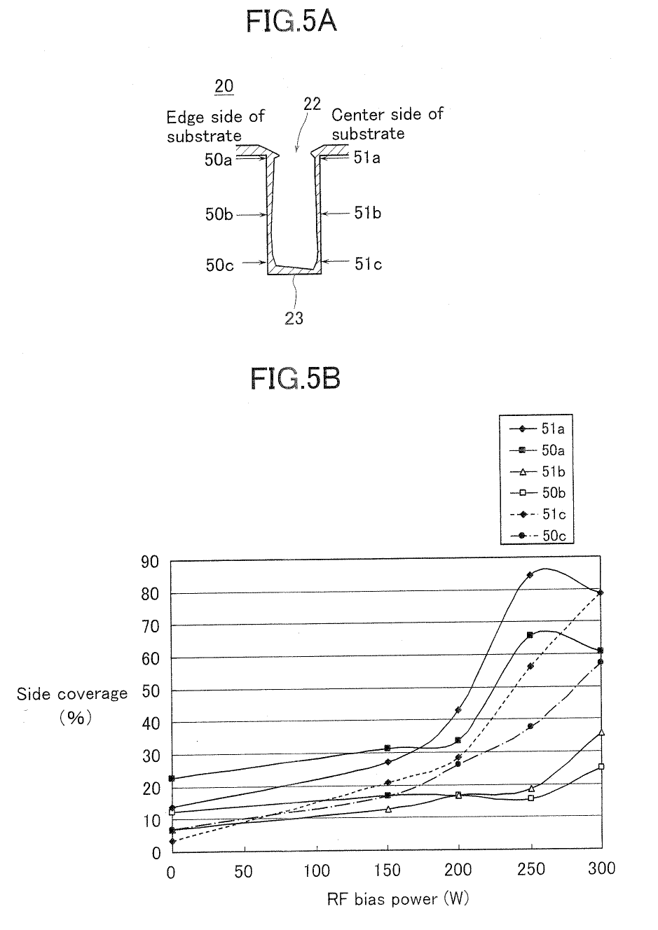

Furthermore, the results of another examination on the correlation between the substrate bias supply power and the thickness of the coating film is shown in FIG. 5. In FIG. 5 (a), a location in the vicinity of the opening portion 22, a location giving the minimum side coverage, and a location in the vicinity of the bottom portion 23, along the sidewall portion of the edge side of the substrate in a hole 20 positioned in the edge side of the substrate are denoted as 50a, 50b and 50c, respectively. A location in the vicinity of the opening portion 22, a location giving the minimum side coverage, and a location in the vicinity of the bottom portion 23, along the sidewall portion in a hole 20 positioned in the center side of the substrate are denoted as 51a, 51b and 51c, respectively. The relationship between side coverage and the substrate bias supply power in these locations of sidewall portions, 50a, 50b, 50c, 51a, 51b and 51c is shown in FIG. 5 (b). The correlation between side coverage and the substrate bias supply power in the above-described locations of sidewall portions is observed from FIG. 5 (b). Thereby, it is known that the overall film thickness increases in each location accompanied with the increase in the substrate bias supply power; and that the side coverage values for the sidewall portions in the holes both in the edge side and in the center side on the substrate are the practically close to each other within the power range between 100 and 250 W. It is also known that the side coverage values substantially agree within the power range preferably between 150 and 200 W.

By detailed examinations by FIGS. 4 and 5, it is known that difference in the thickness of the coating films in the height direction of the sidewall portions, and difference in the thickness of the coating films along the sidewall portions both in the substrate center side and in the substrate edge side, that is, the non-symmetry of difference in film thickness is correlated with the substrate bias supply power, and thus the difference in film thickness can be eliminated by controlling the substrate bias supply power.

In the present invention, as shown in the following examples, as the method for controlling the substrate bias supply power, a modulation technique, that is, the film thickness distribution in the hole under a given condition is previously obtained to prepare database. Next, the substrate bias supply power appropriate for eliminating difference in film thickness in each location is applied using the database to realize the elimination of the above-described difference in thickness of the coating film.

In the embodiment of the present invention, although the subject of coating is a contact hole, it is needless to say that the present invention is not limited thereto, but can be applied to through-holes, wiring grooves or simple step shapes if the subject of coating has a sidewall portion formed by the irregularity on a substrate.

### EXAMPLES

Using the film forming apparatus of FIG. 1, a barrier metal film consisting of a Ta single substance metal was formed on the surface of a contact hole on a substrate 7.

### Example 1

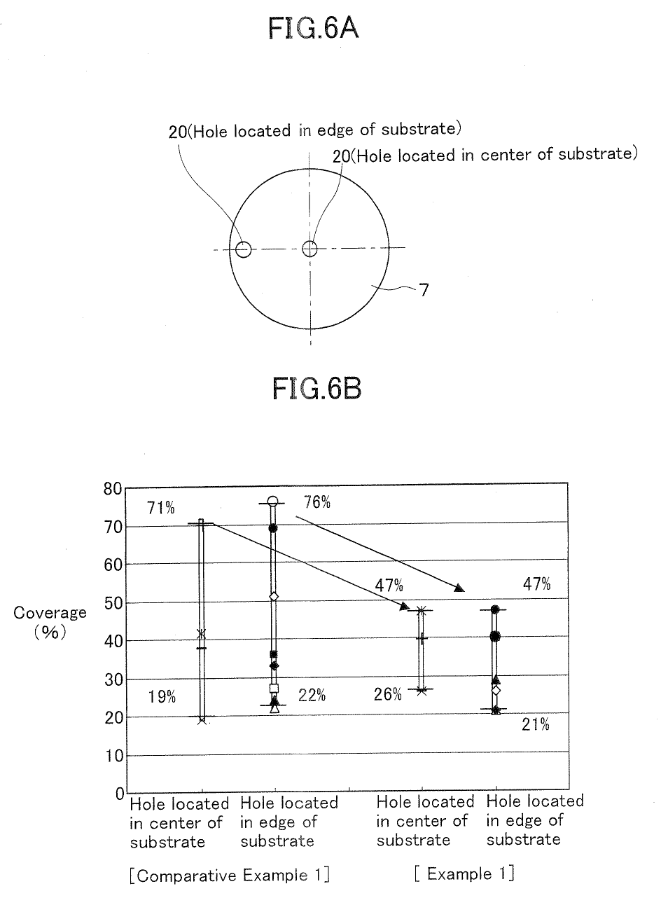

In this case, the RF substrate bias supply power applied during bias sputtering film forming was continuously varied with a desired electric power varied within the range between 0 and 350 W. Thus, the barrier metal film was formed, and two contact holes positioned on the substrate center portion and on the substrate edge side (refer to FIG. 6 (a)) were observed. At this time, the thickness distribution of the barrier metal film formed on the sidewall portion and on the bottom portion of each contact hole is standardized by the thickness of the film formed on the surface of the portion without irregularity and is shown as coverage values (side coverage and step coverage) in FIG. 6 (b).

### Comparative Example 1

A barrier metal film was formed in the same manner as in Example 1, except that the RF substrate bias supply power fixed to 200 W was applied. The film thickness distribution is shown as coverage values in FIG. 6 (b).

From Example 1 and Comparative Example 1, it is known that the degree of dispersion of the coverage can be much lowered by controlling the above-described substrate bias supply power. Thereby, since the thickness of the coating film formed on the sidewall portion and on the bottom portion of the hole can be made uniform throughout the entire wafer, the burying stability of wirings and the diffusion preventing effect of wiring materials can be improved.

Example 2

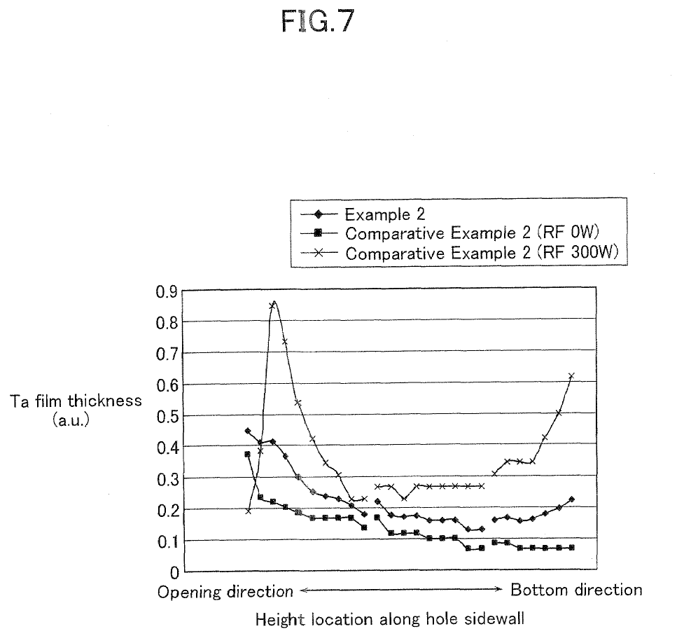

The thickness of a barrier metal film consisting of a Ta single substance metal formed under the same conditions as in Example 1 was measured in the height direction of the sidewall portion (from the bottom to the vicinity of the opening of the hole), and the results as shown in FIG. 7 were obtained.

### Comparative Example 2

The thickness of Ta barrier metal films formed when ordinary sputtering film forming was performed without applying the RF substrate bias supply power (RF 0W), and when the RF substrate bias supply power was fixed at 300 W (RE 300W) were measured in the height direction of the sidewall portions, and the results as shown in FIG. 7 were obtained.

When Example 2 was compared with Comparative Example 2, the overall shortage of coverage or the deterioration of coverage in the bottom direction as the RF supply power was 0 W was not observed, overhang growth in such a scale as to close the opening portion as the RF supply power was 300 W was also not observed, and it was known that the thickness of the coating film in the sidewall portions could be made uniform.

According to the bias sputtering film forming process of the present invention, as obviously known from the above description, since the substrate bias supply power is increased or decreased so as to eliminate difference in the thickness of the coating film generated in the height direction of the sidewall portions or on the surfaces of the bottoms of the concave portion, when the coating films are formed on the sidewall portions or on the bottom surfaces of the irregularity of a substrate using the bias sputtering film forming process, the coating films having a uniform thickness can be formed. Therefore, the coating films having good film thickness distribution can be formed, and when such coating films are used as barrier layers or seed layers for plating, the product quality can be improved.

What is claimed is:

1. A bias sputtering film forming process for forming a thin film by applying both voltages of a cathode voltage and a substrate bias voltage, wherein a thin film is formed on a substrate whereon an irregularity is formed in the state wherein only the cathode voltage out of said both voltages is applied, and sputtering film forming is performed while varying said substrate bias voltage so that the thickness of said thin film formed on the surfaces on the sidewalls and on the bottoms of said irregularity is substantially uniform.

2. The bias sputtering film forming process according to claim 1, wherein said cathode voltage is also varied, in said bias sputtering film forming performed while varying said substrate bias voltage.

3. The bias sputtering film forming process according to claim 1 or 2, wherein sputtering particles coming from a target enter substantially vertically in said substrate.

4. The bias sputtering film forming process according to claim 1 or 2, wherein said thin film is used as a barrier layer, or a seed layer for electrolytic plating.

5. A bias sputtering film forming apparatus comprising an AC power source or a DC power source of variable output against substrate electrodes and a control system, wherein said control system makes the cathode voltage set to a predetermined voltage previously, stores the substrate bias voltage value when the substrate is apart from the target by a predetermined distance and the thickness distribution of thin films on each of said surfaces corresponding to said substrate bias voltage value as reference data, and controls the output of said power source by bias voltage functions produced by selecting the substrate bias voltage value that makes said film thickness substantially uniform from said reference data when each of said surfaces is formed.

6. The bias sputtering film forming apparatus according to claim 5, in which said apparatus further comprises a power source of variable output against said cathode, wherein said control system also varies the cathode voltage by controlling the output of said cathode power source, in said bias sputtering film forming performed by controlling the output of said substrate power source based on said bias voltage functions.
